(19) United States
(12) Patent Application Publication
(10) Pub. No.: US 2024/0260391 A1
(43) Pub. Date: Aug. 1, 2024

(54) TRANSPARENT DISPLAY DEVICE

(71) Applicant: LG Display Co., Ltd., Seoul (KR)

(72) Inventors: Kanghyun KIM, Paju-si (KR); Sejin KIM, Incheon (KR); Heetae LIM, Gimpo-si (KR)

(21) Appl. No.: 18/324,801

(22) Filed: May 26, 2023

(30) Foreign Application Priority Data
Jan. 31, 2023 (KR) 10-2023-0012789

(51) Int. Cl. H10K 59/80; H10K 59/123; H10K 59/35; H10K 59/38

(52) U.S. Cl. CPC H10K 59/80518; H10K 59/123; H10K 59/351; H10K 59/353; H10K 59/38

(57) ABSTRACT

The present disclosure relates to a transparent display device, according to an aspect of the present disclosure, the transparent display device includes a first substrate including a first area and a second area, the transparent display device includes an anode disposed on the first substrate and including a first anode disposed in the first area and a second anode corresponding to the second area, further, the transparent display device includes a first emission layer disposed on the first anode in the first area, and a second emission layer disposed on the first emission layer and the second anode in the second area, furthermore, the transparent display device includes a cathode disposed on the second emission layer. The first anode and the second anode include at least one transparent electrode layer, and the first anode further includes a reflective layer.

### CROSS-REFERENCE TO RELATED APPLICATIONS

This application claims the priority of Korean Patent Application No. 10-2023-0012789 filed on Jan. 31, 2023, in the Korean Intellectual Property Office, the disclosure of which is incorporated herein by reference.

### BACKGROUND

### Technical Field

The present disclosure relates to a transparent display device, and more particularly, to a transparent display device with improved luminance.

### Description of the Related Art

In recent years, with the advent of the information age, the field of displays to visually express electrical information signals has rapidly developed. As such, various display devices having excellent performance such as thin profile, light weight and low power consumption have rapidly been developed.

Among the various display devices, an organic light emitting display device is a self-emission display device that emits light by exciting an organic compound. The organic light emitting display device does not require a backlight used in a liquid crystal display (LCD) and thus has advantages of a thin profile, light weight, and a simple manufacturing process. Further, the organic light emitting display device is widely used because it may be manufactured at a low temperature, has a high response speed of 1 ms or less as well as low power consumption, a wide viewing angle and a high contrast.

The organic light emitting display device includes organic light emitting diodes (OLEDs) that convert electric energy into light energy. The OLED includes an anode, a cathode, and an organic emission layer between the anode and the cathode. The OLED display device is configured such that the OLED emits light while excitons formed by combining holes from the anode and electrons from the cathode inside the emission layer fall from an excited state to a ground state, and thus displays an image.

In recent years, research of a transparent display device is actively carried out. The transparent display device refers to a display device through which a user may perceive an object, etc., positioned behind a display panel in addition to visual information implemented in the display panel, in front of the display panel. To this end, the transparent display device includes an emission area in which driving elements are disposed and an input image is implemented, and a transmission area that transmits external light. In the transparent display device, the area occupied by the transmission area needs to be sufficiently secured so that the user may perceive background information positioned behind the display panel more clearly. Also, in order to maintain high luminance, the aperture ratio needs to be secured at a predetermined level or more.

### BRIEF SUMMARY

As described above, it is beneficial for a transparent display device to have a transmission area having a predetermined size or more. Therefore, the ratio of an emission area decreases as compared with an element having the same size, which results in a decrease in luminance and lifespan.

One or more embodiments of the present disclosure provide a transparent display device which has a transmission area having a predetermined size or more and is improved in luminance and lifespan.

The technical benefits of the present disclosure are not limited to the above-mentioned benefits, and other benefits, which are not mentioned above, can be clearly understood by those skilled in the art from the following descriptions.

According to an aspect of the present disclosure, the transparent display device includes a first substrate including a first area and a second area. Also, the transparent display device includes an anode disposed on the first substrate and including a first anode disposed in the first area and a second anode corresponding to the second area. Further, the transparent display device includes a first emission layer disposed on the first anode in the first area, and a second emission layer disposed on the first emission layer and the second anode in the second area. Furthermore, the transparent display device includes a cathode disposed on the second emission layer. The first anode and the second anode include at least one transparent electrode layer, and the first anode further includes a reflective layer.

Other detailed matters of the exemplary embodiments are included in the detailed description and the drawings.

According to the present disclosure, it is possible to provide a transparent display device which has a sufficient transmission area and is improved in luminance and lifespan. The transmission area is configured to variably operate in a transmission mode in which light is transmitted and an emission mode in which external light is transmitted and light is emitted. Therefore, the present disclosure contributes to low power consumption of a transparent display device.

In the transparent display device according to the present disclosure, a variable emission and transmission area variably operates in a transmission mode and an emission mode. Therefore, even when exposed to an environment in which the intensity of ambient light is high, the transparent display device has high luminance and thus has excellent display quality.

In the transparent display device according to the present disclosure, the placement of sub-pixels can reduce scan mura occurring when an organic layer is formed through a solution process.

In the transparent display device according to the present disclosure, the placement of sub-pixels can suppress color mixing between adjacent sub-pixels when an organic layer is formed through a solution process.

The effects according to the present disclosure are not limited to the contents exemplified above, and more various effects are included in the present specification.

### BRIEF DESCRIPTION OF THE SEVERAL VIEWS OF THE DRAWINGS

The above and other aspects, features and other advantages of the present disclosure will be more clearly understood from the following detailed description taken in conjunction with the accompanying drawings, in which:

FIG. 1 is a plan view of a transparent display device according to an exemplary embodiment of the present disclosure;

FIG. 2 is an enlarged plan view of a pixel in the transparent display device according to an exemplary embodiment of the present disclosure;

FIG. 3 is a cross-sectional view as taken along a line I-I′ of FIG. 2;

FIG. 4 is a schematic cross-sectional view of an organic light emitting diode disposed in each of a plurality of sub-pixels and a variable emission and transmission area;

FIG. 5 is an enlarged plan view of a pixel in a transparent display device according to another exemplary embodiment of the present disclosure;

FIG. 6 is an enlarged plan view of a pixel in a transparent display device according to yet another exemplary embodiment of the present disclosure;

FIG. 7A is a diagram for explaining a method of forming an emission layer by inkjet printing in a pixel structure shown in FIG. 5;

FIG. 7B is a diagram for explaining a method of forming an emission layer by inkjet printing in a pixel structure shown in FIG. 6; and

FIG. 8 is an enlarged plan view of a pixel in a transparent display device according to still another exemplary embodiment of the present disclosure.

### DETAILED DESCRIPTION

Advantages and characteristics of the present disclosure and a method of achieving the advantages and characteristics will be clear by referring to exemplary embodiments described below in detail together with the accompanying drawings. However, the present disclosure is not limited to the exemplary embodiments disclosed herein but will be implemented in various forms. The exemplary embodiments are provided by way of example only so that those skilled in the art can fully understand the disclosures of the present disclosure and the scope of the present disclosure.

The shapes, sizes, ratios, angles, numbers, and the like illustrated in the accompanying drawings for describing the exemplary embodiments of the present disclosure are merely examples, and the present disclosure is not limited thereto. Like reference numerals generally denote like elements throughout the specification. Further, in the following description of the present disclosure, a detailed explanation of known related technologies may be omitted to avoid unnecessarily obscuring the subject matter of the present disclosure. The terms such as “including.” “having.” and “consist of” used herein are generally intended to allow other components to be added unless the terms are used with the term “only”. Any references to singular may include plural unless expressly stated otherwise.

Components are interpreted to include an ordinary error range even if not expressly stated.

When the position relation between two parts is described using the terms such as “on,” “above,” “below,” and “next,” one or more parts may be positioned between the two parts unless the terms are used with the term “immediately” or “directly.”

When an element or layer is disposed “on” another element or layer, another layer or another element may be interposed directly on the other element or therebetween.

Although the terms “first,” “second,” and the like are used for describing various components, these components are not confined by these terms. These terms are merely used for distinguishing one component from the other components. Therefore, a first component to be mentioned below may be a second component in a technical concept of the present disclosure.

Like reference numerals generally denote like elements throughout the specification.

A size and a thickness of each component illustrated in the drawing are illustrated for convenience of description, and the present disclosure is not limited to the size and the thickness of the component illustrated.

The features of various embodiments of the present disclosure can be partially or entirely adhered to or combined with each other and can be interlocked and operated in technically various ways, and the embodiments can be carried out independently of or in association with each other.

In the present disclosure, the transparency of a transparent display device refers to the degree of transparency at which a user at least perceives an object behind the display device. For example, the transparent display device refers to a display device with a transparency of at least 20%. In the present disclosure, the transparency of the transparent display device refers to a value obtained by dividing the amount of light transmitted through the transparent display device by the total amount of incident light except for light which has entered a transmission area of the transparent display device and has been reflected from the interface of layers of the transparent display device.

Hereinafter, the present disclosure will be described with reference to the accompanying drawings.

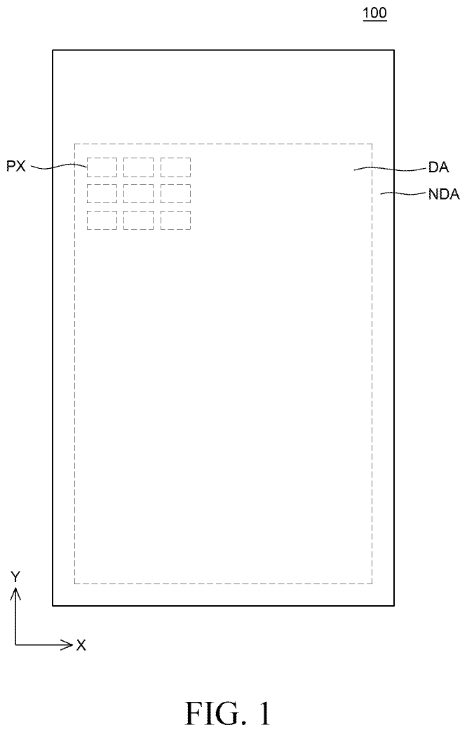

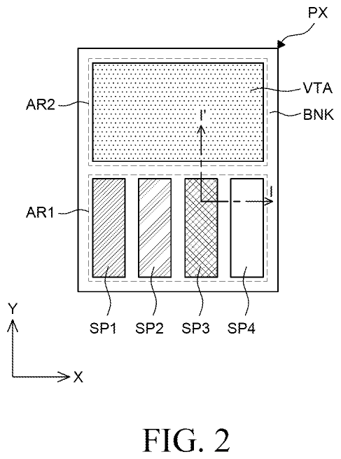

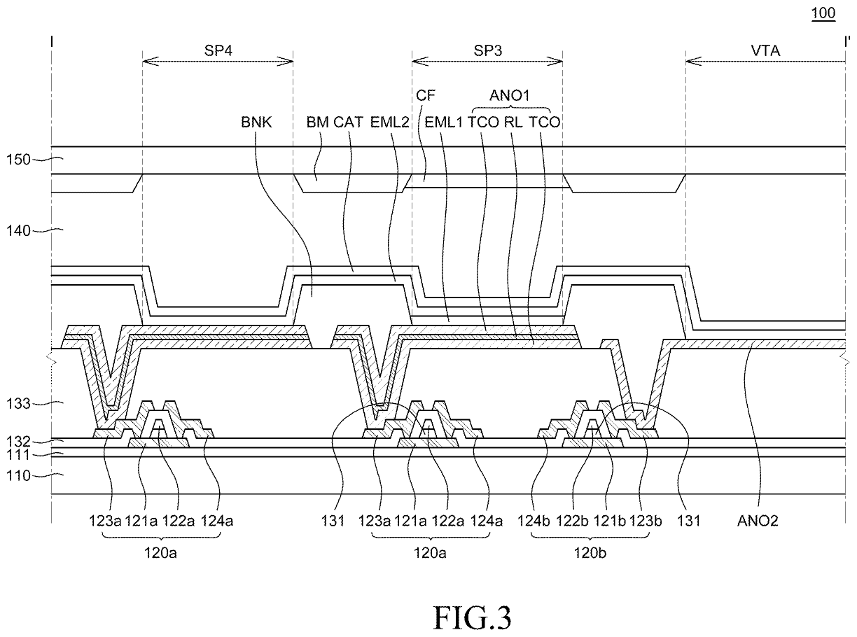

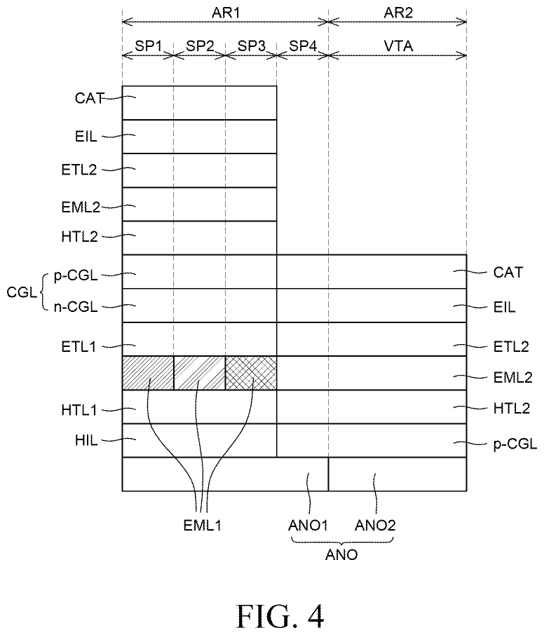

FIG. 1 through FIG. 4 are diagrams for explaining a transparent display device according to an exemplary embodiment of the present disclosure. FIG. 1 is a plan view of the transparent display device according to an exemplary embodiment of the present disclosure. FIG. 2 is an enlarged plan view of a pixel in the transparent display device according to an exemplary embodiment of the present disclosure. FIG. 3 is a cross-sectional view as taken along a line I-I′ of FIG. 2. FIG. 4 is a schematic cross-sectional view of an organic light emitting diode disposed in each of a plurality of sub-pixels and a variable emission and transmission area.

Referring to FIG. 1 through FIG. 4, a transparent display device 100 according to an exemplary embodiment of the present disclosure includes a first substrate 110, thin film transistors 120a and 120b and a planarization layer 133. Also, the transparent display device 100 includes a first anode ANO1, a second anode ANO2, a bank BNK, a first emission layer EML1, a second emission layer EML2, a cathode CAT, a color filter layer CF, a black matrix BM and a second substrate 150. In the present disclosure, the transparent display device 100 may be a top emission organic light emitting display device. Thus, light emitted from an organic light emitting diode is output toward an upper part of the transparent display device 100.

The first substrate 110 supports various components of the transparent display device. The substrate 110 may be divided into a display area DA and a non-display area NDA. The display area DA is an area where a plurality of pixels PX is disposed to display an image. The plurality of pixels PX including an emission unit for displaying an image and driving circuits for driving the pixels PX may be disposed in the display area DA. The non-display area NDA surrounds the display area DA. The non-display area NDA is an area where an image is not displayed and various lines, driver ICs and printed circuit boards for driving the pixels PX and the driving circuits disposed in the display area DA are disposed. For example, various ICs such as a gate driver IC and a data driver IC may be disposed in the non-display area NDA.

The first substrate 110 may be made of a transparent insulating material. For example, the first substrate 110 may be a glass substrate or a plastic substrate. For example, the plastic substrate may be made of a material selected from polyimide, polyethersulfone, polyethylene terephthalate, polyetherimide, polymethylmethacrylate and polycarbonate, but is not limited thereto.

Each of the plurality of pixels PX may be divided into a first area AR1 and a second area AR2. The first area AR1 is an area where a plurality of sub-pixels SP1, SP2, SP3 and SP4 is disposed, and the second area AR2 is a variable emission and transmission area VTA. In the present exemplary embodiment, a pixel is illustrated as including four sub-pixels and a variable emission and transmission area. However, this is only one embodiment of the present disclosure, but is not limited thereto.

The first sub-pixel SP1, the second sub-pixel SP2, the third sub-pixel SP3 and the fourth sub-pixel SP4 are disposed to be spaced apart from each other along a first direction (X-axis direction). The variable emission and transmission area VTA is disposed in a second direction (Y-axis direction) perpendicular to the first direction (X-axis direction) to be spaced apart from the first sub-pixel SP1, the second sub-pixel SP2, the third sub-pixel SP3 and the fourth sub-pixel SP4. However, the present disclosure is not limited thereto. The placement of the sub-pixels SP1, SP2, SP3 and SP4 and the variable emission and transmission area VTA may be changed according to the need or design. In the drawings, each of the plurality of sub-pixels SP1, SP2, SP3 and SP4 and the variable emission and transmission area VTA is illustrated as having a rectangular shape, but is not limited thereto and may have other shapes.

The sub-pixels SP1, SP2, SP3 and SP4 are elements for displaying one color. Each of the plurality of pixels PX may include the first sub-pixel SP1, the second sub-pixel SP2, the third sub-pixel SP3 and the fourth sub-pixel SP4 that display different colors from each other. For example, the first sub-pixel SP1 may be red sub-pixel, the second sub-pixel SP2 may be a green sub-pixel, the third sub-pixel SP3 may be a blue sub-pixel, and the fourth sub-pixel SP4 may be a white sub-pixel, but the present disclosure is not limited thereto.

Each of the plurality of pixels PX includes the variable emission and transmission area VTA. Each layer disposed in the variable emission and transmission area VTA is substantially transparent. Thus, the variable emission and transmission area VTA may transmit light.

As described above, in order for a user to perceive background information positioned behind the display device, a transmission area having a predetermined size or more needs to be secured. For example, the variable emission and transmission area VTA may be formed to account for 30% to 70% of the size of a pixel, but is not limited thereto. The size of the variable emission and transmission area VTA may vary according to the need or design. As for a conventional transparent display device, when a transmission area is formed to have a predetermined size or more in a pixel to secure transparency, the aperture ratio decreases, which results in a decrease in luminance and lifespan. Herein, the aperture ratio refers to the ratio of a light emitting area to a pixel.

In the transparent display device 100 according to an exemplary embodiment of the present disclosure, each of the plurality of pixels PX includes the variable emission and transmission area VTA that variably operates in a transmission mode and an emission mode. The variable emission and transmission area VTA operates in a transmission mode in which light is transmitted when an organic light emitting diode formed in the variable emission and transmission area VTA is not driven. Also, the variable emission and transmission area VTA operates in an emission mode in which external light is transmitted and light is emitted when the organic light emitting diode formed in the variable emission and transmission area VTA is driven. The organic light emitting diode formed in the variable emission and transmission area VTA is made of a substantially transparent material. Thus, the organic light emitting diode may emit light and transmit external light in the emission mode at the same time.

As described above, the variable emission and transmission area VTA serves as a transparent part that transmits light in the transmission mode and emits light in the emission mode. Thus, the user may clearly perceive information positioned behind the transparent display device 100 and the luminance is improved. Therefore, the usability of the transparent display device 100 may be improved. Also, since the variable emission and transmission area VTA variably operates in the transmission mode and the emission mode, the transparent display device 100 of the present disclosure has high luminance even when exposed to an environment in which the intensity of ambient light is high. Thus, the transparent display device 100 has excellent display quality and allows the user to view information positioned behind the transparent display device 100.

A buffer layer 111 is formed on the first substrate 110. The buffer layer 111 may suppress permeation of moisture or foreign matters and block introduction of impurities through the first substrate 110 during a process. The buffer layer 111 may be configured by a single layer or a plurality of layers when needed. For example, the buffer layer 111 may be made of an inorganic material having excellent barrier properties. For example, the buffer layer 111 may be made of a material selected from silicon oxide, silicon nitride, silicon oxynitride, but is not limited thereto. Also, the buffer layer 111 may be scarcely affected by moisture or foreign matters, or may be omitted depending on the design of the transparent display device 100.

A thin film transistor 120 is disposed on the buffer layer 111. The thin film transistor 120 includes a plurality of first thin film transistors 120a and a plurality of second thin film transistors 120b.

The first thin film transistor 120a serves to drive an organic light emitting diode formed in each of the first sub-pixel SP1, the second sub-pixel SP2, the third sub-pixel SP3 and the fourth sub-pixel SP4. The plurality of first thin film transistors 120a is electrically connected to the organic light emitting diodes formed in the first sub-pixel SP1, the second sub-pixel SP2, the third sub-pixel SP3 and the fourth sub-pixel SP4, respectively. Specifically, the plurality of first thin film transistors 120a is electrically connected to the first anodes ANO1 corresponding to the first sub-pixel SP1, the second sub-pixel SP2, the third sub-pixel SP3 and the fourth sub-pixel SP4, respectively.

The second thin film transistor 120b serves to drive an organic light emitting diode formed in the variable emission and transmission area VTA. The second thin film transistor 120b is electrically connected to the organic light emitting diode formed in the variable emission and transmission area VTA. Specifically, the second thin film transistor 120b is electrically connected to the second anode ANO2 corresponding to the variable emission and transmission area VTA. Thus, the organic light emitting diode formed in the variable emission and transmission area VTA may variably operate in the transmission mode and the emission mode when needed.

The first thin film transistor 120a and the second thin film transistor 120b may include gate electrodes 122a and 122b, active layers 121a and 122b, source electrodes 123a and 123b and drain electrodes 124a and 124b, respectively.

For example, each of the plurality of first thin film transistors 120a includes a first gate electrode 122a, a first active layer 121a, a first source electrode 123a and a first drain electrode 124a. Specifically, the first active layer 121a is disposed on the buffer layer 111, and a gate insulating layer 131 for insulating the first gate electrode 122a is disposed on the first active layer 121a. Also, an interlayer insulating layer 132 for insulating the first gate electrode 122a, the first source electrode 123a and the first drain electrode 124a is disposed therebetween. Further, the first source electrode 123a and the first drain electrode 124a are disposed to be in contact with the first active layer 121a on the interlayer insulating layer 132. The first source electrode 123a is electrically connected to the first anode ANO1, but is not limited thereto. The first drain electrode 124a may be electrically connected to the first anode ANO1 when needed.

For example, each of the plurality of second thin film transistors 120b includes a second gate electrode 122b, a second active layer 121b, a second source electrode 123b and a second drain electrode 124b. Specifically, the second active layer 121b is disposed on the buffer layer 111, and the gate insulating layer 131 for insulating the second gate electrode 122b is disposed on the second active layer 121b. Also, the interlayer insulating layer 132 for insulating the second gate electrode 122b, the second source electrode 123b and the second drain electrode 124b is disposed therebetween. Further, the second source electrode 123b and the second drain electrode 124b are disposed to be in contact with the second active layer 121b on the interlayer insulating layer 132. The second source electrode 123b is electrically connected to the second anode ANO2, but is not limited thereto. The second drain electrode 124b may be electrically connected to the second anode ANO2 when needed.

Each of the first thin film transistor 120a and the second thin film transistor 120b may be located under the first anode ANO1 and the bank BNK. In this case, the variable emission and transmission area VTA is further improved in transparency.

However, the present disclosure is not limited thereto. The configuration and placement of the first and second thin film transistors 120a and 120b may be changed according to the need, and the first and second thin film transistors 120a and 120b may have various configurations and structures.

A protective layer may also be disposed on the first and second thin film transistors 120a and 120b. The protective layer protects the first and second thin film transistors 120a and 120b in follow-up processes.

In the present disclosure, only a driving thin film transistor is illustrated among various thin film transistors that may be included in the transparent display device 100. However, the transparent display device 100 may further include various thin film transistors such as a switching thin film transistor. Also, in the present disclosure, each of the first and second thin film transistors 120a and 120b is described as having a coplanar structure, but is not limited thereto. An inverted staggered thin film transistor may also be used.

The planarization layer 133 is disposed on the thin film transistor 120. The planarization layer 133 planarizes an upper part of the thin film transistor 120. Also, the planarization layer 133 covers a step difference between an area where the thin film transistor 120 is disposed and an area where the thin film transistor 120 is not disposed. The planarization layer 133 includes a contact hole for electrically connecting the thin film transistor 120 and an anode ANO.

A plurality of organic light emitting diodes corresponding to the first sub-pixel SP1, the second sub-pixel SP2, the third sub-pixel SP3, the fourth sub-pixel SP4 and the variable emission and transmission area VTA, respectively, is disposed on the planarization layer 133. Each of the plurality of organic light emitting diodes includes an anode, an emission layer and a cathode, which will be described in detail.

The anode ANO is disposed on the planarization layer 133. The anode ANO is divided into parts corresponding to the first sub-pixel SP1, the second sub-pixel SP2, the third sub-pixel SP3, the fourth sub-pixel SP4 and the variable emission and transmission area VTA, respectively.

The anode ANO includes the first anode ANO1 and the second anode ANO2. The first anode ANO1 is disposed in the first area AR1, and the second anode ANO2 is disposed in the second area AR2. The first anode ANO1 is disposed on the planarization layer 133 corresponding to each of the first sub-pixel SP1, the second sub-pixel SP2, the third sub-pixel SP3 and the fourth sub-pixel SP4. The second anode ANO2 is disposed on the planarization layer 133 corresponding to the variable emission and transmission area VTA which is the second area AR2.

The first anode ANO1 is a reflective anode that reflects light emitted from the first emission layer EML1 and the second emission layer EML2 to be output toward the upper part of the transparent display device 100. Accordingly, the first anode ANO1 includes a reflective layer RL and at least one transparent electrode layer TCO. For example, the first anode ANO1 may have a triple-layer structure in which the reflective layer RL is interposed between the two transparent electrode layers TCO. In this case, the adhesion and electrical properties between the first source electrode 123a of the first thin film transistor 120a and the first anode ANO1 are enhanced.

The reflective layer RL may be made of a conductive material having high reflectivity that enables light emitted from the first emission layer EML1 and the second emission layer EML2 to be reflected toward the upper part of the transparent display device 100. For example, the reflective layer RL may be made of a reflective metal material such as aluminum (Al), silver (Ag), molybdenum (Mo), titanium (Ti), etc.

The second anode ANO2 is disposed on the planarization layer 133 corresponding to the variable emission and transmission area VTA. The variable emission and transmission area VTA is configured to transmit light in order to secure transparency. Thus, the second anode ANO2 is formed as a transparent anode that transmits light. For example, the second anode ANO2 may be formed as a transparent electrode layer without a reflective layer. Accordingly, the variable emission and transmission area VTA transmits light, and, thus, the user may perceive an object behind the transparent display device 100.

Each of the transparent electrode layer TCO of the first anode ANO1 and the second anode ANO2 is made of a transparent conductive material having a high work function to smoothly supply holes to the first emission layer EML1 and the second emission layer EML2. For example, each of the transparent electrode layer TCO of the first anode ANO1 and the second anode ANO2 may be made of a transparent conductive material such as indium tin oxide, indium zinc oxide, etc.

The bank BNK is disposed on the planarization layer 133 and the anode ANO. The bank BNK is disposed on the planarization layer 133 to expose at least a part of the anode ANO. The bank BNK is disposed to cover the edge of the anode ANO. The bank BNK partitions pixels adjacent to each other. Also, the bank BNK partitions the sub-pixels SP1, SP2, SP3 and SP4 adjacent to each other. Further, the bank BNK partitions the sub-pixels SP1, SP2, SP3 and SP4 from the variable emission and transmission area VTA.

For example, the bank BNK may be made of polyimide, acryl resin, benzocyclobutene, cardo-based resin, etc., but is not limited thereto.

The first emission layer EML1 and the second emission layer EML2 are disposed on the anode ANO.

The first emission layer EML1 is disposed on the first anode ANO1 corresponding to each of the first sub-pixel SP1, the second sub-pixel SP2 and the third sub-pixel SP3 in the first area AR1. The first emission layer EML1 may be configured to emit light of the same color as each of the corresponding sub-pixels SP1, SP2 and SP3. Specifically, the first emission layer EML1 corresponding to the first sub-pixel SP1 is configured to emit red light and the first emission layer EML1 corresponding to the second sub-pixel SP2 is configured to emit green light. Also, the first emission layer EML1 corresponding to the third sub-pixel SP3 is configured to emit blue light.

The second emission layer EML2 is disposed on the first emission layer EML1. The second emission layer EML2 is disposed in both the first area AR1 and the second area AR2. Thus, unlike the first emission layer EML1, the second emission layer EML2 is not patterned. Also, the second emission layer EML2 may be formed on the first emission layer EML1 in all of the first sub-pixel SP1, the second sub-pixel SP2, the third sub-pixel SP3, the fourth sub-pixel SP4 and the variable emission and transmission area VTA through a single process. That is, the second emission layer EML2 may be a common layer disposed in all of the first sub-pixel SP1, the second sub-pixel SP2, the third sub-pixel SP3, the fourth sub-pixel SP4 and the variable emission and transmission area VTA.

As described, the second emission layer EML2 may be laminated on the first emission layer EML1 in all of the first sub-pixel SP1, the second sub-pixel SP2, the third sub-pixel SP3, the fourth sub-pixel SP4 and the variable emission and transmission area VTA. In this case, a decrease in luminance of the transparent display device 100 caused by the transmission area may be solved. Further, the luminance of the transparent display device 100 may be improved and the lifespan of the transparent display device 100 may be increased.

The second emission layer EML2 may be configured to emit blue light or white light. In this case, the variable emission and transmission area VTA serves as a transparent part that transmits light in the transmission mode, and emits light and transmits external light in the emission mode. Thus, a decrease in luminance caused by the transmission area may be solved. Also, the second emission layer EML2 is formed in all of the first sub-pixel SP1, the second sub-pixel SP2, the third sub-pixel SP3, the fourth sub-pixel SP4 and the variable emission and transmission area VTA. Thus, the luminance of the transparent display device 100 may be greatly improved, which contributes to an increase in lifespan and improvement in display quality.

The cathode CAT is disposed on the second emission layer EML2. The cathode CAT may be made of a conductive material having a low work function to smoothly supply electrons. Like the second emission layer EML2, the cathode CAT is not patterned. The cathode CAT is configured by a single layer on the second emission layer EML2 in all of the first sub-pixel SP1, the second sub-pixel SP2, the third sub-pixel SP3, the fourth sub-pixel SP4 and the variable emission and transmission area VTA. The cathode CAT may be formed to have a very small thickness to be substantially transparent in order for light to be output toward the upper part of the transparent display device 100.

An encapsulation layer may be disposed on the cathode CAT. The encapsulation layer protects the components disposed thereunder against external moisture, oxygen, foreign matters or the like. The encapsulation layer may be configured by a single layer or a plurality of layers. For example, the encapsulation layer may have a triple-layer structure in which an organic encapsulation layer is interposed between two inorganic encapsulation layers, but is not limited thereto. The encapsulation layer may be made of a transparent material to transmit light emitted from the first and second emission layers EML1 and EML2.

The second substrate 150 is disposed to face the first substrate 110. The second substrate 150 protects the organic light emitting diodes and thin film transistors constituting the transparent display device 100 against external shock, moisture, foreign matters or the like. Like the first substrate 110, the second substrate 150 may be a glass substrate or a plastic substrate.

The black matrix BM and the color filter layer CF are disposed on one surface of the second substrate 150 which faces the first substrate 110. The black matrix BM and the color filter layer CF enable light of colors corresponding to the respective sub-pixels SP1, SP2, SP3 and SP4 to be output and suppress color mixing between the sub-pixels SP1, SP2, SP3 and SP4 adjacent to each other. Also, the black matrix BM and the color filter layer CF may compensate for a decrease in contrast ratio caused by external light reflection.

The color filter layer CF includes a plurality of color filters corresponding to the first sub-pixel SP1, the second sub-pixel SP2 and the third sub-pixel SP3, respectively. Each of the plurality of color filters is configured to output light of the same color as each of the corresponding sub-pixels. For example, the color filter layer CF may include a red color filter corresponding to the first sub-pixel SP1, a green color filter corresponding to the second sub-pixel SP2 and a blue color filter corresponding to the third sub-pixel SP3.

A color filter may or may not be disposed in the fourth sub-pixel SP4 which is a white sub-pixel. For example, if the second emission layer EML2 emits white light, a color filter may not be disposed in the fourth sub-pixel SP4. However, the present disclosure is not limited thereto. Even if the second emission layer EML2 emits white light, a color filter may be selectively disposed corresponding to the fourth sub-pixel SP4 when needed in order to improve color reproduction and color impression. Meanwhile, if the second emission layer EML2 emits blue light, a color filter may be disposed corresponding to the fourth sub-pixel SP4. The color filter corresponding to the fourth sub-pixel SP4 contains a color conversion material capable of converting blue light emitted from the second emission layer EML2 into white light. Thus, the fourth sub-pixel SP4 emits white light.

A color filter is not disposed in the variable emission and transmission area VTA. However, the present disclosure is not limited thereto. A color filter may be selectively disposed in the variable emission and transmission area VTA when needed in order to improve the display quality. If the color filter is disposed in the variable emission and transmission area VTA, it may be made of a substantially transparent material.

The black matrix BM may be disposed between a plurality of color filters. The black matrix BM suppresses color mixing between the sub-pixels SP1, SP2, SP3 and SP4 adjacent to each other and color mixing between the sub-pixels SP1. SP2. SP3 and SP4 and the variable emission and transmission area VTA. Thus, the black matrix BM may be formed corresponding to the bank BNK.

In order to bond the first substrate 110 to the second substrate 150, a transparent resin layer 140 may be disposed between the encapsulation layer, the black matrix BM and the color filter layer CF. The transparent resin layer 140 fills an empty space between the cathode CAT, the black matrix BM and the color filter layer CF.

FIG. 3 illustrates only the first emission layer EML1 and the second emission layer EML2 between the anode ANO and the cathode CAT for the convenience of description. However, the transparent display device 100 may further include various functional layers between the anode ANO and the first and second emission layers EML1 and EML2 and between the cathode CAT and the second emission layer EML2 to improve emission efficiency and lifespan.

Hereinafter, various functional layers disposed between the anode ANO and the cathode CAT and a method of manufacturing the same will be described in detail with reference to FIG. 4 together. FIG. 4 is a cross-sectional view of an organic light emitting diode disposed in each of a plurality of sub-pixels and a variable emission and transmission area.

As described above, the first anode ANO1 is disposed corresponding to each of the first sub-pixel SP1, the second sub-pixel SP2, the third sub-pixel SP3 and the fourth sub-pixel SP4. Also, the second anode ANO2 is disposed corresponding to the variable emission and transmission area VTA. The first anode ANO1 and the second anode ANO2 may be easily formed through a deposition process due to their material properties.

A hole injection layer HIL is disposed on the first anode ANO1 corresponding to each of the first sub-pixel SP1, the second sub-pixel SP2 and the third sub-pixel SP3. The hole injection layer HIL is disposed between the anode ANO made of an inorganic material and a first hole transport layer HTL1 made of an inorganic material to improve interface characteristics. The hole injection layer HIL may be formed through a solution process such as inkjet printing. The hole injection layer HIL may be formed to be separated for each of the first sub-pixel SP1, the second sub-pixel SP2 and the third sub-pixel SP3. Alternatively, the hole injection layer HIL may be formed as a single layer throughout the first sub-pixel SP1, the second sub-pixel SP2 and the third sub-pixel SP3.

The first hole transport layer HTL1 is disposed on the hole injection layer HIL. The first hole transport layer HTL facilitates transport of holes to the first emission layer EML1. The first hole transport layer HTL may be formed through a solution process such as inkjet printing. The first hole transport layer HTL may be formed to be separated for each of the first sub-pixel SP1, the second sub-pixel SP2 and the third sub-pixel SP3. Alternatively, the first hole transport layer HTL may be formed as a single layer throughout the first sub-pixel SP1, the second sub-pixel SP2 and the third sub-pixel SP3.

The first emission layer EML1 is disposed on the first hole transport layer HTL. As described above, the first emission layer EML1 is formed in a separate manner to emit light of the same color as each of the first sub-pixel SP1, the second sub-pixel SP2 and the third sub-pixel SP3. The first emission layer EML1 may contain a host material and an emission dopant. The first emission layer EML1 of the first sub-pixel SP1 may contain a red host material and a red emission dopant, and the first emission layer EML1 of the second sub-pixel SP2 may contain a green host material and a green emission dopant. Also, the first emission layer EML1 of the third sub-pixel SP3 may contain a blue host material and a blue emission dopant. The first emission layer EML1 may be formed to be separated for each of the first sub-pixel SP1, the second sub-pixel SP2 and the third sub-pixel SP3 through a solution process such as inkjet printing.

A first electron transport layer ETL1 is disposed on the first emission layer EML1. The first electron transport layer ETL1 improves transport of electrons to the first emission layer EML1. The first electron transport layer ETL1 may be formed through a solution process such as inkjet printing. The first electron transport layer ETL1 may be formed to be separated for each of the first sub-pixel SP1, the second sub-pixel SP2 and the third sub-pixel SP3. Alternatively, the first electron transport layer ETL1 may be formed as a single layer throughout the first sub-pixel SP1, the second sub-pixel SP2 and the third sub-pixel SP3.

A charge generation layer CGL is disposed between the first emission layer EML1 and the second emission layer EML2. The charge generation layer CGL adjusts charge balance between the first emission layer EML1 and the second emission layer EML2 and thus improves emission efficiency. The charge generation layer CGL includes an n-type charge generation layer n-CGL adjacent to the first emission layer EML1 and a p-type charge generation layer p-CGL adjacent to the second emission layer EML2. The n-type charge generation layer n-CGL improves injection and transport of electrons to the first emission layer EML1, and the p-type charge generation layer p-CGL improves injection and transport of holes to the second emission layer EML2.

The n-type charge generation layer n-CGL is disposed on the first electron transport layer ETL1 corresponding to the first sub-pixel SP1, the second sub-pixel SP2 and the third sub-pixel SP3. The n-type charge generation layer n-CGL may be formed through a solution process such as inkjet printing. The n-type charge generation layer n-CGL may be formed to be separated for each of the first sub-pixel SP1, the second sub-pixel SP2 and the third sub-pixel SP3. Alternatively, the n-type charge generation layer n-CGL may be formed as a single layer throughout the first sub-pixel SP1, the second sub-pixel SP2 and the third sub-pixel SP3.

The p-type charge generation layer p-CGL is formed in the first sub-pixel SP1, the second sub-pixel SP2, the third sub-pixel SP3, the fourth sub-pixel SP4 and the variable emission and transmission area VTA. For example, the p-type charge generation layer p-CGL may be a common layer disposed in all of the first sub-pixel SP1, the second sub-pixel SP2, the third sub-pixel SP3, the fourth sub-pixel SP4 and the variable emission and transmission area VTA. That is, the p-type charge generation layer p-CGL is formed in all of the first sub-pixel SP1, the second sub-pixel SP2, the third sub-pixel SP3, the fourth sub-pixel SP4 and the variable emission and transmission area VTA through a single process. Thus, the p-type charge generation layer p-CGL is disposed on the n-type charge generation layer n-CGL in an area corresponding to the first sub-pixel SP1, the second sub-pixel SP2 and the third sub-pixel SP3. Also, the p-type charge generation layer p-CGL is disposed on the first anode ANO1 in an area corresponding to the fourth sub-pixel SP4. Further, the p-type charge generation layer p-CGL is disposed the second anode ANO2 in the variable emission and transmission area VTA. Accordingly, the p-type charge generation layer p-CGL improves injection and transport of holes to the second emission layer EML2.

For example, the p-type charge generation layer p-CGL may be formed through a deposition process. As described above, the p-type charge generation layer p-CGL is disposed on different surfaces and thus is preferable to be formed through a deposition process. Thus, the p-type charge generation layer p-CGL may be formed as a common layer disposed in all of the first sub-pixel SP1, the second sub-pixel SP2, the third sub-pixel SP3, the fourth sub-pixel SP4 and the variable emission and transmission area VTA through a deposition process.

A second hole transport layer HTL2 is disposed on the p-type charge generation layer p-CGL. The second hole transport layer HTL2 improves transport of holes to the second emission layer EML2. Thus, charge balance is improved and emission efficiency may be improved. The second hole transport layer HTL2 is disposed corresponding to the first sub-pixel SP1, the second sub-pixel SP2, the third sub-pixel SP3, the fourth sub-pixel SP4 and the variable emission and transmission area VTA. For example, the second hole transport layer HTL2 may be formed as a common layer disposed in all of the first sub-pixel SP1, the second sub-pixel SP2, the third sub-pixel SP3, the fourth sub-pixel SP4 and the variable emission and transmission area VTA through a deposition process.

The second emission layer EML2 is disposed on the second hole transport layer HTL2. The second emission layer EML2 may be a common layer disposed in all of the first sub-pixel SP1, the second sub-pixel SP2, the third sub-pixel SP3, the fourth sub-pixel SP4 and the variable emission and transmission area VTA. That is, the p-type charge generation layer p-CGL is formed in all of the first sub-pixel SP1, the second sub-pixel SP2, the third sub-pixel SP3, the fourth sub-pixel SP4 and the variable emission and transmission area VTA through a single process. The second emission layer EML2 may be made of a material that emits blue light or white light. For example, the second emission layer EML2 may be formed as a single layer in all of the first sub-pixel SP1, the second sub-pixel SP2, the third sub-pixel SP3, the fourth sub-pixel SP4 and the variable emission and transmission area VTA through a deposition process.

A second electron transport layer ETL2 is disposed on the second emission layer EML2. The second electron transport layer ETL2 improves transport of electrons to the second emission layer EML2. The second electron transport layer ETL2 is disposed corresponding to the first sub-pixel SP1, the second sub-pixel SP2, the third sub-pixel SP3, the fourth sub-pixel SP4 and the variable emission and transmission area VTA. For example, the second electron transport layer ETL2 may be formed as a common layer disposed in all of the first sub-pixel SP1, the second sub-pixel SP2, the third sub-pixel SP3, the fourth sub-pixel SP4 and the variable emission and transmission area VTA through a deposition process.

An electron injection layer EIL is disposed on the second electron transport layer ETL2. The electron injection layer EIL injects electrons supplied from the cathode CAT into the second emission layer EML2. The electron injection layer EIL is disposed corresponding to the first sub-pixel SP1, the second sub-pixel SP2, the third sub-pixel SP3, the fourth sub-pixel SP4 and the variable emission and transmission area VTA. For example, the electron injection layer EIL may be formed as a common layer disposed in all of the first sub-pixel SP1, the second sub-pixel SP2, the third sub-pixel SP3, the fourth sub-pixel SP4 and the variable emission and transmission area VTA through a deposition process.

The cathode CAT is disposed on the electron injection layer EIL. The cathode CAT may be formed as a common layer disposed in all of the first sub-pixel SP1, the second sub-pixel SP2, the third sub-pixel SP3, the fourth sub-pixel SP4 and the variable emission and transmission area VTA through a deposition process.

Each of the second anode ANO2, the p-type charge generation layer p-CGL, the second hole transport layer HTL2, the second emission layer EML2, the second electron transport layer ETL2, the electron injection layer EIL and the cathode CAT disposed in the variable emission and transmission area VTA is made of a substantially transparent material. Thus, the variable emission and transmission area VTA increases the transparency of the display device 100 in order for the user to perceive information positioned behind the transparent display device 100. Also, the variable emission and transmission area VTA transmits external light, and operates in the emission mode when a voltage is applied to the second anode ANO2 and the cathode CAT. In the emission mode, holes injected from the second anode ANO2 and electrons injected from the cathode CAT are recombined into excitons in the second emission layer EML2 to emit light. Thus, a decrease in luminance and lifespan caused by the transmission area may be improved. Particularly, if the transmission area accounts for 50% or more of the size of a pixel, the size of an opening relatively decreases, which causes a further decrease in luminance and an increase in driving voltage. Therefore, the power consumption of the transparent display device increases and the lifespan of the transparent display device decreases. However, the transparent display device according to an exemplary embodiment of the present disclosure variably emits light by means of the transmission area that transmits external light and emits light with an electric field. Thus, the conventional problem of a decrease in luminance and lifespan may be solved.

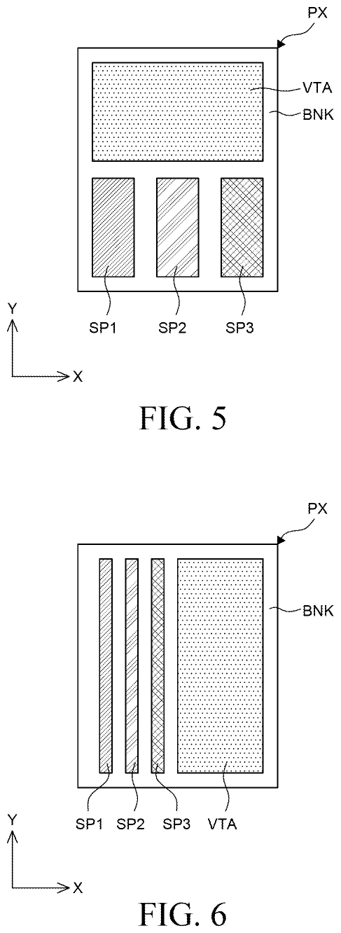

FIG. 5 is an enlarged plan view of a pixel in a transparent display device according to another exemplary embodiment of the present disclosure. Referring to FIG. 5, the transparent display device according to another exemplary embodiment of the present disclosure is substantially the same as the transparent display device shown in FIG. 1 through FIG. 4 except that each of a plurality of pixels does not include a fourth sub-pixel and the sizes of first, second and third sub-pixels relatively increase. Therefore, a redundant description will be omitted.

Accordingly, the transparent display device according to another exemplary embodiment of the present disclosure will be described with reference to FIG. 5 together with FIG. 1 through FIG. 4.

First, referring to FIG. 5, in the transparent display device according to another exemplary embodiment of the present disclosure, each of the plurality of pixels PX includes a plurality of sub-pixels SP1, SP2 and SP3 and the variable emission and transmission area VTA. The first sub-pixel SP1, the second sub-pixel SP2 and the third sub-pixel SP3 are disposed to be spaced apart from each other along the first direction (X-axis direction). Also, the variable emission and transmission area VTA is disposed in the second direction (Y-axis direction) perpendicular to the first direction (X-axis direction) to be spaced apart from the first sub-pixel SP1, the second sub-pixel SP2 and the third sub-pixel SP3.

The first sub-pixel SP1 may be a red sub-pixel, the second sub-pixel SP2 may be a green sub-pixel, and the third sub-pixel SP3 may be a blue sub-pixel.

As shown in FIG. 1 through FIG. 4, the organic light emitting diode disposed in the variable emission and transmission area VTA is configured by the same functional layer and emission layer as the organic light emitting diode disposed in the fourth sub-pixel SP4, which is a white sub-pixel, except that the former includes a second anode and the latter includes a first anode. Accordingly, in a pixel PX structure shown in FIG. 5, the variable emission and transmission area VTA serves as a white sub-pixel.

For example, an organic light emitting diode in which the second emission layer EML2 is disposed between the second anode ANO2 and the cathode CAT is formed in the variable emission and transmission area VTA. The second emission layer EML2 is configured to emit blue light or white light. Accordingly, when a voltage is applied to the second anode ANO2 and the cathode CAT, the second emission layer EML2 emits blue light or white light. If the second emission layer EML2 emits blue light, a color filter capable of converting blue light into white light is disposed at a position corresponding to the variable emission and transmission area VTA. In this case, the color filter corresponding to the variable emission and transmission area VTA is made of a substantially transparent material. Accordingly, the variable emission and transmission area VTA may serve as a transmission area as well as a white sub-pixel in the transparent display device.

In the pixel PX structure shown in FIG. 5, the second anode ANO2 that does not include a reflective layer is disposed in the variable emission and transmission area VTA serving as a white sub-pixel. Accordingly, in the variable emission and transmission area VTA, a part of light emitted from the second emission layer EML2 may be transmitted through the back surface.

The transparent display device according to the present exemplary embodiment includes the variable emission and transmission area VTA. Thus, the transparent display device may operate in the emission mode in which external light is transmitted and holes injected from the second anode ANO2 and electrons injected from the cathode CAT are recombined into excitons in the second emission layer EML2 to emit light when a voltage is applied to the second anode ANO2 and the cathode CAT. Therefore, the transparent display device according to the present exemplary embodiment may solve a decrease in luminance and lifespan caused by a decrease in opening due to a transmission area of a conventional transparent display device.

Also, the pixel PX structure shown in FIG. 5 does not include a fourth sub-pixel, which is a white sub-pixel, and, thus, is simpler than the pixel PX structure shown in FIG. 2. Accordingly, if the pixel PX is configured as shown in FIG. 5, it is possible to reduce a process margin and improve a process efficiency.

FIG. 6 is an enlarged plan view of a pixel in a transparent display device according to yet another exemplary embodiment of the present disclosure. Referring to FIG. 6, the transparent display device according to yet another exemplary embodiment of the present disclosure is substantially the same as the transparent display device shown in FIG. 5 except the shapes and placement of first, second and third sub-pixels and a variable emission and transmission area in each of a plurality of pixels. Therefore, a redundant description will be omitted.

Referring to FIG. 6, the first sub-pixel SP1, the second sub-pixel SP2, the third sub-pixel SP3 and the variable emission and transmission area VTA are disposed to be spaced apart from each other along the first direction (X-axis direction). The first sub-pixel SP1, the second sub-pixel SP2, the third sub-pixel SP3 and the variable emission and transmission area VTA are disposed parallel to each other.

In a pixel PX structure shown in FIG. 6, the first sub-pixel SP1, the second sub-pixel SP2 and the third sub-pixel SP3 are each formed into a rectangular shape having a greater aspect ratio than the first sub-pixel SP1, the second sub-pixel SP2 and the third sub-pixel SP3, respectively, shown in FIG. 5. Therefore, in the pixel PX structure shown in FIG. 6, the first sub-pixel SP1, the second sub-pixel SP2 and the third sub-pixel SP3 are each formed into a rectangular shape with a greater length in the second direction (Y-axis direction) as compared with the first sub-pixel SP1, the second sub-pixel SP2 and the third sub-pixel SP3, respectively, shown in FIG. 5.

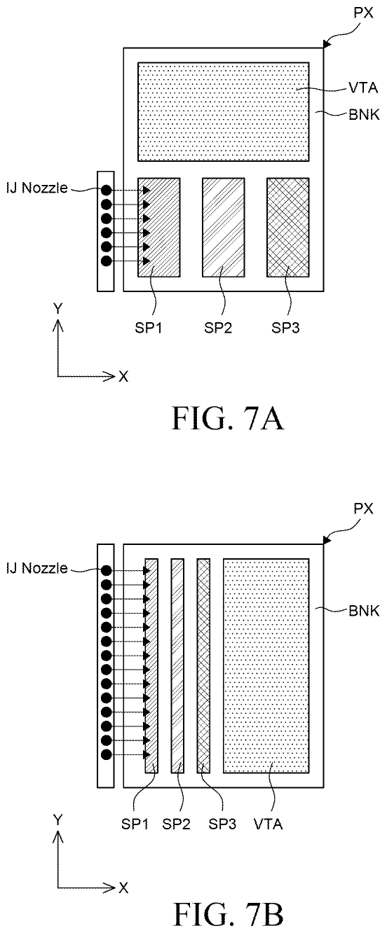

In this case, inkjet printing may be facilitated and scan mura may be improved. In this regard, description will be made with reference to FIG. 7A and FIG. 7B in detail. FIG. 7A is a diagram for explaining a method of forming an emission layer by inkjet printing in a pixel structure shown in FIG. 5, and FIG. 7B is a diagram for explaining a method of forming an emission layer by inkjet printing in a pixel structure shown in FIG. 6.

As shown in FIG. 7A and FIG. 7B, each of the first sub-pixel SP1, the second sub-pixel SP2 and the third sub-pixel SP3 may have a great aspect ratio. In this case, when a first emission layer in each of the first sub-pixel SP1, the second sub-pixel SP2 and the third sub-pixel SP3 is formed by inkjet printing, the number of inkjet nozzles IJ Nozzle may be increased. As the number of inkjet nozzles IJ Nozzle increases, the first emission layer having uniform surface characteristics may be formed by suppressing scan mura.

Accordingly, the transparent display device including the pixel PX structure shown in FIG. 6 includes the variable emission and transmission area VTA and thus has excellent transparency with improved luminance and lifespan. Also, the transparent display device provides excellent display quality by suppressing scan mura.

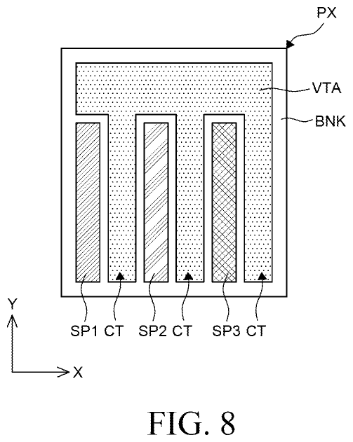

FIG. 8 is an enlarged plan view of a pixel in a transparent display device according to still another exemplary embodiment of the present disclosure. Referring to FIG. 8, the transparent display device according to still another exemplary embodiment of the present disclosure is substantially the same as the transparent display devices shown in FIG. 5 and FIG. 6 except the shapes and placement of first, second and third sub-pixels and a variable emission and transmission area in each of a plurality of pixels. Therefore, a redundant description will be omitted.

Referring to FIG. 8, each of the plurality of pixels PX includes the first sub-pixel SP1, the second sub-pixel SP2, the third sub-pixel SP3 and the variable emission and transmission area VTA.

The variable emission and transmission area VTA is formed into a comb shape having a plurality of comb teeth CT. In other words, the variable emission and transmission area VTA may be formed into fingers.

The first sub-pixel SP1, the second sub-pixel SP2 and the third sub-pixel SP3 are disposed to be spaced apart from each other with the comb tooth CT therebetween. That is, the variable emission and transmission area VTA has an empty space between the adjacent comb teeth CT, and each of the first sub-pixel SP1, the second sub-pixel SP2 and the third sub-pixel SP3 is disposed in the empty space. Therefore, the first sub-pixel SP1, the second sub-pixel SP2 and the third sub-pixel SP3 are disposed parallel to each other with the comb tooth CT therebetween. Also, each of the first sub-pixel SP1, the second sub-pixel SP2 and the third sub-pixel SP3 is disposed to alternate with the comb tooth CT.

Accordingly, the first sub-pixel SP1, the second sub-pixel SP2 and the third sub-pixel SP3 are disposed with the comb tooth CT of the variable emission and transmission area VTA therebetween. Thus, the first sub-pixel SP1, the second sub-pixel SP2 and the third sub-pixel SP3 adjacent to each other are spaced apart by a greater distance than those of the pixel PX structure shown in FIG. 6. Therefore, it is possible to suppress color mixing between adjacent sub-pixels during inkjet printing. That is, the variable emission and transmission area VTA is formed into a comb shape having the plurality of comb teeth CT and the first sub-pixel SP1, the second sub-pixel SP2 and the third sub-pixel SP3 are disposed with the comb tooth CT therebetween. In this case, a color mixing margin is increased due to the comb teeth CT. Therefore, it is possible to suppress color mixing of inks during inkjet printing and thus possible to improve a process efficiency and minimize color mixing defects.

Accordingly, the transparent display device including the pixel PX structure shown in FIG. 8 includes the variable emission and transmission area VTA and thus has excellent transparency with improved luminance and lifespan. Also, the transparent display device provides excellent process efficiency and display quality by suppressing scan mura and color mixing of inks during inkjet printing.

Hereinafter, the effects of the present disclosure will be described in more detail with reference to Embodiments and Comparative Embodiments. However, the following Embodiments are set forth to illustrate the present disclosure, but the scope of the disclosure is not limited thereto by the following Embodiments.

### Embodiment 1

A transparent organic light emitting diode including a red sub-pixel, a green sub-pixel, a blue sub-pixel, a white sub-pixel and a variable emission and transmission area configured as shown in FIG. 1 through FIG. 4 was fabricated.

### Comparative Embodiment 1

A first substrate in which a red sub-pixel, a green sub-pixel, a blue sub-pixel, a white sub-pixel and a transmission area are defined was prepared. The shapes, sizes and placement of the red sub-pixel, the green sub-pixel, the blue sub-pixel and the white sub-pixel are the same as in Example 1. Also, the shape, size and placement of the transmission area are the same as those of the variable emission and transmission area of Example 1.

An anode having a triple-layer structure of ITO/Ag/ITO was formed corresponding to each of the red sub-pixel, the green sub-pixel, the blue sub-pixel and the white sub-pixel on the first substrate. Then, a hole injection layer, a hole transport layer, a white emission layer, an electron transport layer, an electron injection layer and a cathode were sequentially deposited on the anode. A color filter layer including a color filter corresponding to each of the red sub-pixel, the green sub-pixel and the blue sub-pixel is disposed on the cathode. As a result, a transparent organic light emitting diode was fabricated.

### Comparative Embodiment 2

A first substrate in which a red sub-pixel, a green sub-pixel, a blue sub-pixel, a white sub-pixel and a transmission area are defined was prepared. The shapes, sizes and placement of the red sub-pixel, the green sub-pixel, the blue sub-pixel and the white sub-pixel are the same as in Example 1. Also, the shape, size and placement of the transmission area are the same as those of the variable emission and transmission area of Example 1.

An anode having a triple-layer structure of ITO/Ag/ITO was formed corresponding to each of the red sub-pixel, the green sub-pixel, the blue sub-pixel and the white sub-pixel on the first substrate. Then, a hole injection layer and a first hole transport layer were sequentially formed on the anode by inkjet printing. Thereafter, a red emission layer corresponding to the red sub-pixel, a green emission layer corresponding to the green sub-pixel and a blue emission layer corresponding to the blue sub-pixel were formed on the first hole transport layer by inkjet printing. Then, a first electron transport layer and an n-type charge generation layer were sequentially deposited on the red, green and blue emission layers. Thereafter, a p-type charge generation layer, a second hole transport layer, a white emission layer, a second electron transport layer, an electron injection layer and a cathode were sequentially deposited corresponding to the red sub-pixel, the green sub-pixel, the blue sub-pixel and the white sub-pixel. A color filter layer including a color filter corresponding to each of the red sub-pixel, the green sub-pixel and the blue sub-pixel is disposed on the cathode. As a result, a transparent organic light emitting diode was fabricated.

### Experimental Embodiment

The properties of the transparent organic emitting diodes according to Example 1 and Comparative Examples 1 and 2, respectively, were evaluated. The result of evaluation is shown in Table 1.

TABLE 1

| Classification | | W | transmission area |
|---|---|---|---|
| area ratio | | 1 | 5.3 |
| Comparative | CIEx | 0.273 | — |
| Embodiments 1 | CIEy | 0.285 | — |
| | device efficiency (%) | 74.7 | — |
| Comparative | CIEx | 0.309 | — |
| Embodiments 2 | CIEy | 0.315 | — |
| | device efficiency (%) | 70.5 | — |
| Embodiment 1 | CIEx | 0.309 | 0.255 |
| | CIEy | 0.315 | 0.239 |
| | device efficiency (%) | 70.5 | 20.7 |

Referring to Table 1 above, it may be seen that the transparent organic emitting diode of Embodiment 1 is equivalent in device efficiency for white sub-pixels to those of Comparative Embodiments 1 and 2. Also, it may be seen that the transparent organic emitting diode of Embodiment 1 is identical in color characteristics for white sub-pixels to that of Comparative Embodiment 2. Further, the transparent organic emitting diode of Embodiment 1 exhibits a classification of about 21% in the transmission area unlike those of Comparative Embodiments 1 and 2. Accordingly, the present disclosure provides a transparent organic light emitting display device which is improved in luminance and lifespan by driving a transmission area in an emission mode when needed.

The exemplary embodiments of the present disclosure can also be described as follows:

According to an aspect of the present disclosure, a transparent display device is comprised of a first substrate including a first area and a second area, an anode disposed on the first substrate and including a first anode disposed in the first area and a second anode corresponding to the second area, a first emission layer disposed on the first anode in the first area, a second emission layer disposed on the first emission layer and the second anode in the second area, and a cathode disposed on the second emission layer, wherein the first anode and the second anode include at least one transparent electrode layer, and the first anode further includes a reflective layer.

The second area may transmit light and may be a variable emission and transmission area that emits light when a voltage is applied to the second anode and the cathode.

The second emission layer may be a common layer disposed in both the first area and the second area.

The second emission layer may emit blue light or white light.

The first area may include a first sub-pixel, a second sub-pixel and a third sub-pixel, and the first emission layer may be disposed corresponding to each of the first sub-pixel, the second sub-pixel and the third sub-pixel.

The first sub-pixel may be a red sub-pixel, the second sub-pixel is a green sub-pixel, and the third sub-pixel may be a blue sub-pixel, and the first emission layer corresponding to the first sub-pixel may emit red light, the first emission layer corresponding to the second sub-pixel emits green light, and the first emission layer corresponding to the third sub-pixel may emit blue light.

The first area may further include a fourth sub-pixel, and the fourth sub-pixel may be a white sub-pixel.

The transparent display device may further comprise a hole injection layer disposed on the first anode corresponding to each of the first sub-pixel, the second sub-pixel and the third sub-pixel, a first hole transport layer disposed on the hole injection layer, a first emission layer disposed on the first hole transport layer, and a first electron transport layer disposed on the first emission layer.

The transparent display device may further comprise a charge generation layer including an n-type charge generation layer and a p-type charge generation layer, wherein the n-type charge generation layer may be disposed on the first electron transport layer corresponding to the first sub-pixel, the second sub-pixel and the third sub-pixel, and the p-type charge generation layer may be a common layer disposed in both the first area and the second area on the n-type charge generation layer.

Each of the hole injection layer, the first hole transport layer, the first emission layer, the first electron transport layer and the n-type charge generation layer may be prepared through a solution process.

The p-type charge generation layer may be disposed on the n-type charge generation layer, the first anode corresponding to the fourth sub-pixel and the second anode.

The transparent display device may further comprise a second hole transport layer disposed on the p-type charge generation layer, a second emission layer disposed on the second hole transport layer, a second electron transport layer disposed on the second emission layer, and an electron injection layer disposed on the second electron transport layer.

The p-type charge generation layer, the second hole transport layer, the second emission layer, the second electron transport layer and the electron injection layer may be prepared through a deposition process.

The transparent display device may further comprise a second substrate disposed to face the first substrate, and a color filter layer disposed on one surface of the second substrate which faces the first substrate, wherein the color filter layer may include a plurality of color filters corresponding to the first sub-pixel, the second sub-pixel and the third sub-pixel, respectively.

The transparent display device may further comprise a plurality of thin film transistors disposed on the first substrate and electrically connected to each of the first anode and the second anode.

The first sub-pixel, the second sub-pixel and the third sub-pixel may be disposed to be spaced apart from each other along a first direction, and the variable emission and transmission area may be disposed in a second direction perpendicular to the first direction to be spaced apart from the first sub-pixel, the second sub-pixel and the third sub-pixel.

The first sub-pixel, the second sub-pixel, the third sub-pixel and the variable emission and transmission area may be disposed to be spaced apart from each other along a first direction.

The variable emission and transmission area may be formed into a comb shape having a plurality of comb teeth, and the first sub-pixel, the second sub-pixel and the third sub-pixel may be disposed to be spaced apart from each other with the comb tooth therebetween.

Although the exemplary embodiments of the present disclosure have been described in detail with reference to the accompanying drawings, the present disclosure is not limited thereto and may be embodied in many different forms without departing from the technical concept of the present disclosure. Therefore, the exemplary embodiments of the present disclosure are provided for illustrative purposes only but not intended to limit the technical concept of the present disclosure. The scope of the technical concept of the present disclosure is not limited thereto. Therefore, it should be understood that the above-described exemplary embodiments are illustrative in all aspects and do not limit the present disclosure. The protective scope of the present disclosure should be construed based on all the technical concepts described in the present disclosure.

The various embodiments described above can be combined to provide further embodiments. All of the U.S. patents, U.S. patent application publications, U.S. patent applications, foreign patents, foreign patent applications and non-patent publications referred to in this specification and/or listed in the Application Data Sheet are incorporated herein by reference, in their entirety. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A transparent display device, comprising:
a first substrate including a first area and a second area;
an anode disposed on the first substrate and including a first anode disposed in the first area and a second anode corresponding to the second area;
a first emission layer disposed on the first anode in the first area;
a second emission layer disposed on the first emission layer and the second anode in the second area; and
a cathode disposed on the second emission layer,
wherein the first anode and the second anode include at least one transparent electrode layer, and
wherein the first anode further includes a reflective layer.

2. The transparent display device according to claim 1, wherein the second area transmits light and is a variable emission and transmission area that emits light when a voltage is applied to the second anode and the cathode.

3. The transparent display device according to claim 2, wherein the second emission layer is a common layer disposed in both the first area and the second area.

4. The transparent display device according to claim 3, wherein the second emission layer emits blue light or white light.

5. The transparent display device according to claim 4, wherein the first area includes a first sub-pixel, a second sub-pixel, and a third sub-pixel, and
wherein the first emission layer is disposed corresponding to each of the first sub-pixel, the second sub-pixel, and the third sub-pixel.

6. The transparent display device according to claim 5, wherein the first sub-pixel is a red sub-pixel, the second sub-pixel is a green sub-pixel, and the third sub-pixel is a blue sub-pixel, and
wherein the first emission layer corresponding to the first sub-pixel emits red light, the first emission layer corresponding to the second sub-pixel emits green light, and the first emission layer corresponding to the third sub-pixel emits blue light.

7. The transparent display device according to claim 6, wherein the first area further includes a fourth sub-pixel, and
wherein the fourth sub-pixel is a white sub-pixel.

8. The transparent display device according to claim 7, further comprising:
a hole injection layer disposed on the first anode corresponding to each of the first sub-pixel, the second sub-pixel, and the third sub-pixel;
a first hole transport layer disposed on the hole injection layer;
a first emission layer disposed on the first hole transport layer; and
a first electron transport layer disposed on the first emission layer.

9. The transparent display device according to claim 8, further comprising:
a charge generation layer including an n-type charge generation layer and a p-type charge generation layer,
wherein the n-type charge generation layer is disposed on the first electron transport layer corresponding to the first sub-pixel, the second sub-pixel, and the third sub-pixel, and
wherein the p-type charge generation layer is a common layer disposed in both the first area and the second area on the n-type charge generation layer.

10. The transparent display device according to claim 9, wherein each of the hole injection layer, the first hole transport layer, the first emission layer, the first electron transport layer, and the n-type charge generation layer is prepared through a solution process.

11. The transparent display device according to claim 9, wherein the p-type charge generation layer is disposed on the n-type charge generation layer, the first anode corresponding to the fourth sub-pixel and the second anode.

12. The transparent display device according to claim 11, further comprising:
a second hole transport layer disposed on the p-type charge generation layer;
a second emission layer disposed on the second hole transport layer;
a second electron transport layer disposed on the second emission layer; and
an electron injection layer disposed on the second electron transport layer.

13. The transparent display device according to claim 12, wherein the p-type charge generation layer, the second hole transport layer, the second emission layer, the second electron transport layer and the electron injection layer are prepared through a deposition process.

14. The transparent display device according to claim 5, further comprising:
a second substrate disposed to face the first substrate; and
a color filter layer disposed on one surface of the second substrate which faces the first substrate,
wherein the color filter layer includes a plurality of color filters corresponding to the first sub-pixel, the second sub-pixel, and the third sub-pixel, respectively.

15. The transparent display device according to claim 1, further comprising:
a plurality of thin film transistors disposed on the first substrate and electrically connected to each of the first anode and the second anode.

16. The transparent display device according to claim 5, wherein the first sub-pixel, the second sub-pixel and the third sub-pixel are disposed to be spaced apart from each other along a first direction, and
wherein the variable emission and transmission area is disposed in a second direction transverse to the first direction to be spaced apart from the first sub-pixel, the second sub-pixel, and the third sub-pixel.

17. The transparent display device according to claim 16, wherein the variable emission and transmission area is disposed in a second direction perpendicular to the first direction to be spaced apart from the first sub-pixel, the second sub-pixel, and the third sub-pixel.

18. The transparent display device according to claim 5, wherein the first sub-pixel, the second sub-pixel, the third sub-pixel and the variable emission and transmission area are disposed to be spaced apart from each other along a first direction.

19. The transparent display device according to claim 5, wherein the variable emission and transmission area is formed into a comb shape having a plurality of comb teeth, and
wherein the first sub-pixel, the second sub-pixel, and the third sub-pixel are disposed to be spaced apart from each other with the comb tooth therebetween.
